(19) United States
(12) Patent Application Publication
(10) Pub. No.: US 2024/0175123 A1
(43) Pub. Date: May 30, 2024

(54) Fusion bonding of diamond using thermal SiO2

(71) Applicant: Phononics Ltd, Nesher (IL)

(72) Inventors: Anna Kosinova, Nesher (IL); Inbar Dag, Nesher (IL)

(73) Assignee: Phononics Ltd, Nesher (IL)

(21) Appl. No.: 18/340,022

(22) Filed: Jun. 22, 2023

Related U.S. Application Data
(60) Provisional application No. 63/385,404, filed on Nov. 29, 2022.

(51) Int. Cl. C23C 16/40; C23C 14/10; C23C 14/34; C23C 14/58; C23C 16/24; C23C 16/50; C23C 16/56

(52) U.S. Cl. CPC C23C 16/402; C23C 14/10; C23C 14/34; C23C 14/5853; C23C 14/588; C23C 16/24; C23C 16/50; C23C 16/56; H05K 7/2039

(57) ABSTRACT

A method for manufacturing an item that exhibits a heat dissipating property, the method includes (i) forming a first structure that has a smooth silicon surface and includes a first layer of silicon and a diamond layer, wherein the forming includes depositing the first layer of silicon on the diamond layer, (ii) forming a second structure that has a smooth thermal silicon dioxide surface and includes a layer of thermal silicon dioxide and a second layer of silicon, the forming includes growing the layer of thermal silicon dioxide on the second layer of silicon; (iii) forming a third structure, the forming includes fusion bonding the smooth silicon surface to the smooth thermal silicon dioxide surface; (iv) forming a fourth structure, the forming includes removing the second layer of silicon from the third structure; and (v) fusion bonding a substrate to the smooth thermal silicon dioxide surface to provide the item.

### BACKGROUND

Thermal management is an essential factor which should be taken into account at design of high-performance electronic devices. Self-heating effects limit the power and operation time of semiconductor devices. Using diamond having the high thermal conductivity as a heat spreader instead of silicon or silicon carbide is very promising in terms of efficient heat dissipation from active area of the transistor and increasing device performance.

Fusion bonding with thermal SiO₂ is a key process for the fabrication of silicon-on-insulator (SOI) substrates. In case the interface layer is sufficiently thin in order not to produce the additional thermal barrier, fusion bonding can be used as a technique for bonding diamond heat spreader to a semiconductor wafer. Application of the classical fusion bonding process for diamond wafers is complicated because of the difficulty to get thermal oxide on diamond wafer. As an alternative option, other types of silicone dioxide can be used, like those obtained by PECVD, sputtering or ALD. But each of this oxide type has some issues, which can be hardly overcome. For example, PECVD has many process parameters like precursor, injected gases, RF power, deposition temperature and so on, which can be changed and strongly effect the properties of the deposited oxide. So, the quality of the fusion bonding will highly depend on the properties of oxide deposited under specific conditions in a specific machine. Sputtered oxide was tested to have a low adhesion to diamond substrate. ALD can be a good option, but its deposition rate is very low and the process becomes economically unprofitable.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1 and 2 illustrate an example of a method for manufacturing an item; and

FIGS. 3 and 4 illustrate an example of method for manufacturing an item that exhibits a heat dissipating property.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system.

There are provided methods to fabricate thermal SiO₂ on diamond substrate.

Any of the methods mentioned below can be applied when performing wafer to wafer bonding, die to die bonding, wafer to die bonding as well bonding in the package level.

Thus—the diamond may be a diamond wafer, a diamond die or any other diamond element.

The first method implies growth of thermal oxide from Si layer deposited on diamond substrate. SiO₂ cannot be grown directly on diamond substrate, so the seed layer of Si is needed to be sputtered or deposited. The thickness of Si layer should be minimal from the thermal perspective and at the same time sufficient to grow the required thickness of SiO₂ layer. Diamond surface should be thoroughly cleaned before Si layer deposition in order to remove any contamination or foreign particles. Once Si layer is ready, thermal oxide can be grown by wet or dry oxidation technique. In case dry oxidation is used, the backside of diamond wafer should be protected by some layer, for example, Si₃N₄ to prevent oxidation of diamond surface, which takes place in oxygen atmosphere at high temperatures. Afterwards, oxide should be polished by CMP, so that its final thickness comes to 100-200 nm and roughness is less than 0.5 nm. Now diamond wafer is ready for fusion bonding.

The second method is oxide transfer from Si substrate to diamond using fusion bonding process. Firstly, a thin Si layer should be deposited on the surface of diamond wafer. This could be achieved by sputtering, PECVD, LPCVD, etc. The thickness of this layer should be enough in order to reach the required roughness (<0.5 nm) after CMP. In parallel, growth of thin thermal SiO₂ layer is done on bare Si substrate. It is performed by wet or dry oxidation technique at high temperature. If the roughness of oxide layer is higher than 0.5 nm, CMP should be done. This has to be taken into account during the growth, so that SiO₂ thickness left after CMP will be about 150-300 nm. In case the roughness of the grown oxide layer is within the Spec., polishing can be omitted. Next step is fusion bonding of diamond wafer having polished Si layer on it to Si wafer with polished SiO₂ layer. Bonding can be done at room temperature with subsequent annealing at 200° C. Afterwards, Si should be totally removed. The best way to do it is to remove mechanically most of the material and to continue with wet etching. Stirring and horizontal positioning of the wafer during etching will help to make the process uniform all over the surface. Once Si is fully removed, SiO₂ is in contact with diamond substrate. One should take into account that in case there were bubbles during fusion bonding, so that unbonded areas exist, SiO₂ from these areas won't be in mechanical communication with diamond. It was shown experimentally, that the roughness of the transferred layer is about 1 nm, which means it should be polished. The final post-CMP SiO₂ thickness has to be about 100-200 nm. Once the layer is polished, diamond wafer is ready to be fusion bonded to a semiconductor wafer. Semiconductor wafer to be bonded in this way can be any wafer having Si or SiC substrate (for example, GaN on Si, GaN on SiC, etc.). It can be both pre-fab bare wafer and post-fab device wafer.

Having thermal oxide that is in mechanical communication with the diamond assures high bonding strength and absence of voids under heating to high temperature in case its thickness is about 100-200 nm.

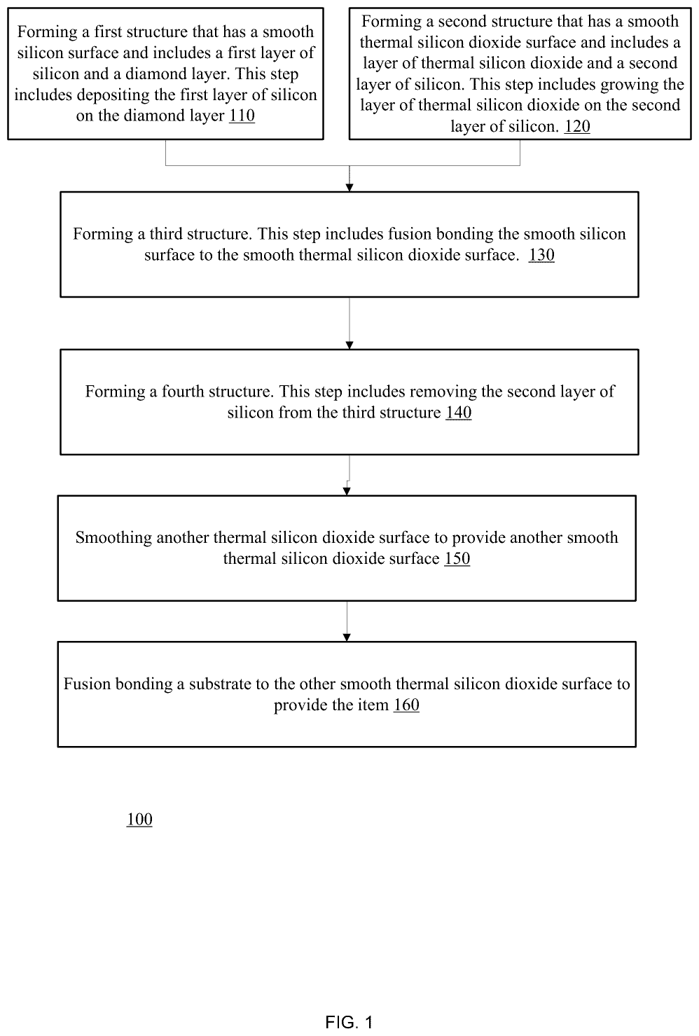

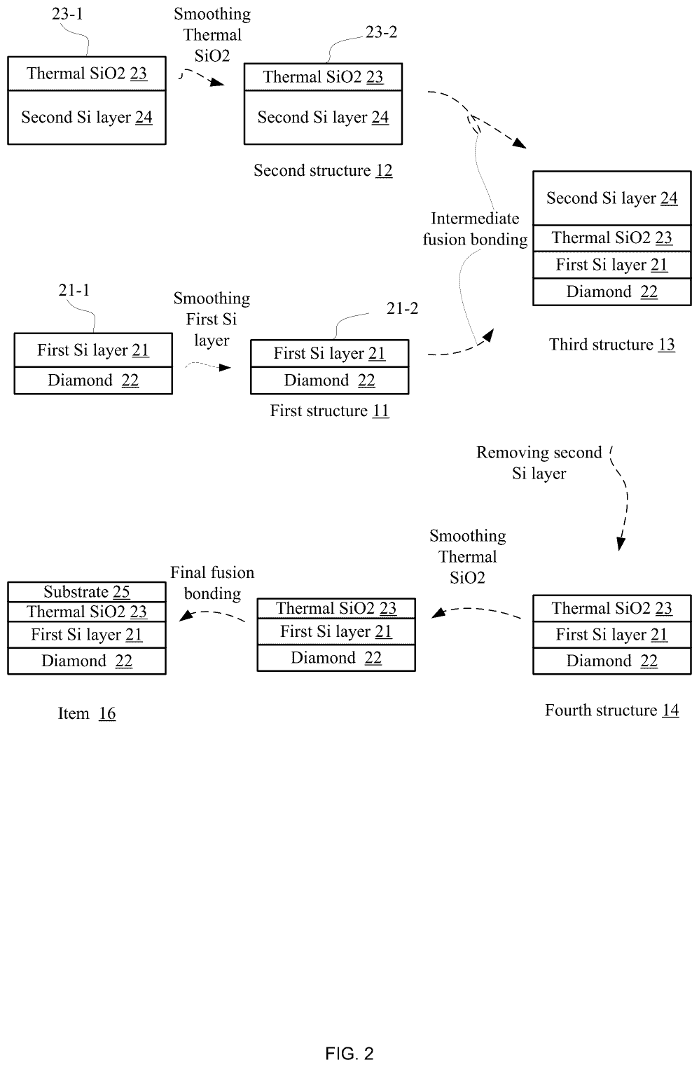

FIGS. 1 and 2 illustrate an example of a method 100 for manufacturing an item that exhibits a heat dissipating property.

Method 100 starts by steps 110 and 120.

Step 110 includes forming a first structure (denoted 11 in FIG. 2) that has a smooth silicon surface (denoted 21-2 in FIG. 2) and includes a first layer of silicon (denoted first Si layer 21 in FIG. 2) and a diamond layer (denoted diamond 22 in FIG. 2), wherein the forming of the first structure comprises depositing the first layer of silicon on the diamond layer. FIG. 2 illustrates that the forming includes smoothing the first silicon layer to provide the smooth silicon surface.

Step 110 may include polishing the first layer of silicon to provide the smooth silicon surface only when a roughness of the first layer exceeds 0.5 nanometers.

Step 110 may include polishing the first layer of silicon to provide the smooth silicon surface.

Step 110 may include depositing the first layer of silicon on the diamond layer by performing at least one out of sputtering, Plasma-Enhanced Chemical Vapor Deposition (PECVD), low pressure Chemical Vapor Deposition (LPCVD), or any other deposition method.

Step 120 includes forming a second structure (denoted 12 in FIG. 2) that has a smooth thermal silicon dioxide surface (denoted 23-2 in FIG. 2) and includes a layer of thermal silicon dioxide (denoted thermal SIO2 23 in FIG. 2) and a second layer of silicon (denoted second Si layer 24 in FIG. 2). The forming of the second structure includes growing the layer of thermal silicon dioxide on the second layer of silicon. FIG. 2 illustrates that the forming includes smoothing the first silicon dioxide layer to provide the smooth silicon dioxide surface.

The smooth thermal silicon dioxide surface and the smooth silicon surface may exhibit a roughness that does not exceed 0.5 nanometer.

A thickness of the layer of thermal silicon dioxide when having the smooth thermal silicon dioxide surface, may range between 100 and 200 nanometers.

Steps 110 and 120 are followed by step 130 of forming a third structure (denoted 13 in FIG. 2), wherein the forming of the third structure incudes fusion bonding the smooth silicon surface to the smooth thermal silicon dioxide surface. This fusion bonding is referred to as an intermediate fusion bonding in FIG. 2.

Step 130 may include executing the intermediate fusion bonding at room temperature, and then annealing at 200° C.

Step 130 is followed by step 140 of forming a fourth structure (denoted fourth structure 14 in FIG. 2). The forming of the fourth structure includes removing the second layer of silicon from the third structure.

Step 140 may include removing of the second layer of silicon from the third structure by etching the second layer of silicon, mechanical polishing or combination of these two methods.

Step 140 may result in roughening another smooth thermal silicon dioxide surface to provide a rough thermal silicon dioxide surface.

Step 140 may be followed by step 150 of smoothing another thermal silicon dioxide surface (exposed after the removal of the second layer of silicon) to provide another smooth thermal silicon dioxide surface.

Step 150 may be followed by step 160 of fusion bonding a substrate to the other smooth thermal silicon dioxide surface to provide the item (denoted 16 in FIG. 2). This fusion bonding is referred to as final fusion bonding in FIG. 2.

The substrate may include at least one material out of silicon, silicon carbide, indium phosphide, gallium nitride, gallium arsenide or silicon germanium.

The substrate may be a semiconductor substrate.

The substrate may be a bare substrate or a patterned substrate that includes structures.

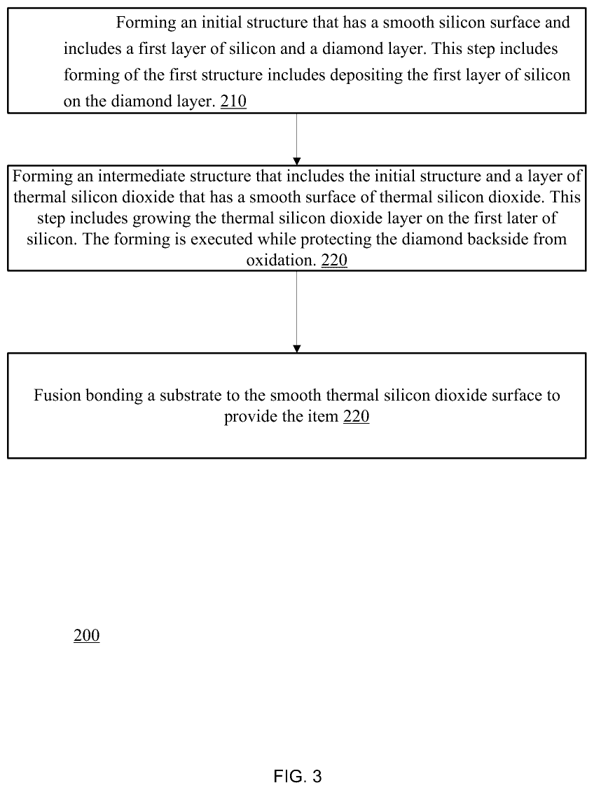

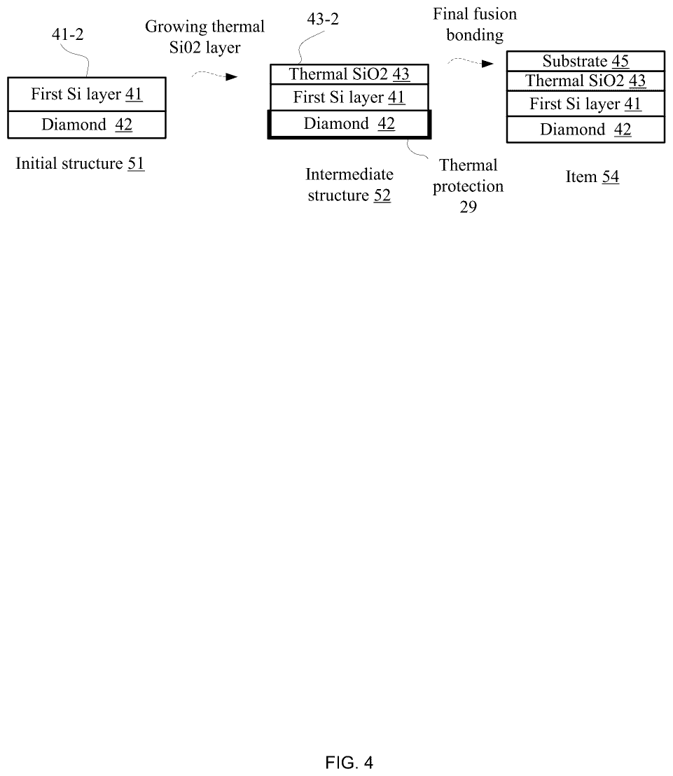

FIGS. 3 and 4 illustrate an example of method 200 for manufacturing an item that exhibits a heat dissipating property.

Method 200 starts by step 210 of forming an initial structure (denoted 51 in FIG. 4) that has a smooth silicon surface (denoted 41-2) and includes a first layer of silicon (denoted first Si layer 41) and a diamond layer (denoted diamond 42), wherein the forming of the first structure includes depositing the first layer of silicon on the diamond layer.

Step 210 is followed by step 220 of forming an intermediate structure (denoted 52 in FIG. 4) that includes the initial structure and a layer of thermal silicon dioxide (denoted Thermal SiO2 43 in FIG. 4) that has a smooth surface (denoted 43-2) of thermal silicon dioxide. The forming of the intermediate layer includes growing the thermal silicon dioxide layer on the first later of silicon. Step 220 includes protecting the diamond backside from oxidation during the growing —see thermal protection 29.

Step 220 is followed by step 230 of fusion bonding a substrate to the smooth thermal silicon dioxide surface to provide the item (denoted 54).

The thermal silicon dioxide layer has thickness that ranges between 150-300 nanometers.

The first silicon layer has thickness that ranges between 70-150 nanometers.

Step 210 may include cleaning a surface of the diamond that interfaces with the first layer of silicon.

Step 220 may be executed by applying a dry oxidation process.

Step 220 may include applying a wet oxidation process.

There may be provided an item as illustrated above and/or in any one of FIGS. 2 and 4 which was manufactured using method 100 or method 200, respectively.

In the foregoing specification, the invention has been described with reference to specific examples of embodiments of the invention. It will, however, be evident that various modifications and changes may be made therein without departing from the broader spirit and scope of the invention as set forth in the appended claims.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method for manufacturing an item that exhibits a heat dissipating property, the method comprising:
forming a first structure that has a smooth silicon surface and comprises a first layer of silicon and a diamond layer, wherein the forming of the first structure comprises depositing the first layer of silicon on the diamond layer;
forming a second structure that has a smooth thermal silicon dioxide surface and comprises a layer of thermal silicon dioxide and a second layer of silicon, wherein the forming of the second structure comprises growing the layer of thermal silicon dioxide on the second layer of silicon;
forming a third structure, wherein the forming of the third structure comprises fusion bonding the smooth silicon surface to the smooth thermal silicon dioxide surface;
forming a fourth structure, wherein the forming of the fourth structure comprises removing the second layer of silicon from the third structure; and
fusion bonding a substrate to the smooth thermal silicon dioxide surface to provide the item.

2. The method according to claim 1, wherein the substrate comprises at least one material out of silicon, silicon carbide, indium phosphide, gallium nitride, gallium arsenide or silicon germanium.

3. The method according to claim 1, wherein the substrate is a semiconductor substrate.

4. The method according to claim 1, wherein a smooth surface of the smooth thermal silicon dioxide surface and the smooth silicon surface exhibits a roughness that does not exceed 0.5 nanometer.

5. The method according to claim 3, wherein the forming of the first structure comprises polishing the first layer of silicon to provide the smooth silicon surface only when a roughness of the first layer exceeds 0.5 nanometers.

6. The method according to claim 1, wherein the forming of the first structure comprises polishing the first layer of silicon to provide the smooth silicon surface.

7. The method according to claim 1, wherein a thickness of the layer of thermal silicon dioxide when having the smooth thermal silicon dioxide surface, ranges between 100 and 200 nanometers.

8. The method according to claim 1, wherein the depositing the first layer of silicon on the diamond layer comprises at least one out of sputtering, Plasma-Enhanced Chemical Vapor Deposition (PECVD), or low pressure Chemical Vapor Deposition (LPCVD).

9. The method according to claim 1, wherein the fusion bonding of the smooth silicon surface to the smooth thermal silicon dioxide surface is executed at room temperature, wherein the method comprises annealing at 200° ° C., following the fusion bonding the smooth silicon surface to the smooth thermal silicon dioxide surface.

10. The method according to claim 1, wherein the removing of the second layer of silicon from the third structure comprises etching the second layer of silicon.

11. The method according to claim 1, wherein the removing of the second layer of silicon roughens the smooth thermal silicon dioxide surface to provide a rough thermal silicon dioxide surface, wherein the method comprises smoothing the rough thermal silicon dioxide surface.

12. The method according to claim 1, wherein the substrate is a bare substrate or a patterned that comprises structures.

13. A method for manufacturing an item that exhibits a heat dissipating property, the method comprising:
forming an initial structure that has a smooth silicon surface and comprises a first layer of silicon and a diamond layer, wherein the forming of the first structure comprises depositing the first layer of silicon on the diamond layer;
forming an intermediate structure that comprises the initial structure and a layer of thermal silicon dioxide that has a smooth surface of thermal silicon dioxide; wherein the forming of the intermediate layer comprises growing the thermal silicon dioxide layer on the first later of silicon; wherein the method comprises protecting the diamond backside from oxidation during the growing; and
fusion bonding a substrate to the smooth thermal silicon dioxide surface to provide the item

14. The method according to claim 13, wherein the thermal silicon dioxide layer has thickness that ranges between 150-300 nanometers.

15. The method according to claim 13, wherein the first silicon layer has thickness that ranges between 70-150 nanometers.

16. The method according to claim 13, wherein the forming of the initial structure comprises cleaning a surface of the diamond that interfaces with the first layer of silicon.

17. The method according to claim 13, wherein the growing of the thermal silicon dioxide layer is executed by applying a dry oxidation process.

18. The method according to claim 13, wherein the growing of the thermal silicon dioxide layer is executed by applying a wet oxidation process.
